(19) United States
(12) Patent Application Publication
(10) Pub. No.: US 2026/0140438 A1
(43) Pub. Date: May 21, 2026

(54) INFLATION HOLDER FOR PHOTOMASK CARRIER

(71) Applicant: GUDENG EQUIPMENT CO., LTD., New Taipei City (TW)

(72) Inventors: An-Pang WANG, New Taipei City (TW); Zhe-Hao ZHANG, New Taipei City (TW); Po-Hsiang CHANG, New Taipei City (TW); Lin-Hsin TU, New Taipei City (TW)

(73) Assignee: GUDENG EQUIPMENT CO., LTD., New Taipei City (TW)

(21) Appl. No.: 18/954,513

(22) Filed: Nov. 20, 2024

(51) Int. Cl. G03F 1/66

(52) U.S. Cl. CPC G03F 1/66

(57) ABSTRACT

An inflation holder for a photomask carrier can be mounted on a carrying stand and hold a photomask carrier. A rectangular loading area is formed on a top of a plate body of the inflation holder and a picking notch is formed on a side of the plate body. Inflation connectors are mounted through the plate body. A detecting assembly has a detector and a press-switch. The inflation connectors and the press-switch are located in the loading area. The detector is located on a periphery of the loading area. The inflation holder can hold the photomask carrier by the rectangular loading area of the plate body and control the inflation connectors by the detector and the press-switch to ensure the flatness of the photomask carrier, so that the inflation connector can inflate the photomask carrier, thereby allowing the inflation holder to be adapted to a rectangular photomask carrier.

### BACKGROUND OF THE INVENTION

### 1. Field of the Invention

The present invention relates to an inflation holder for a photomask carrier, especially to an inflation holder that can carry and inflate a photomask carrier.

### 2. Description of the Prior Arts

In the photolithography process of semiconductors, a photomask is a necessary component to transfer the circuit diagram to a wafer, and the quality and cleanliness of the photomask will affect the product yield. Therefore, to prevent the photomask from being contaminated or damaged during transportation or storage, the photomask will be stored in a photomask carrier. The photomask carrier will be placed on an inflation holder, and clean gas is introduced into the photomask carrier through the inflation connector of the inflation holder, thereby blocking dust and moisture and providing a better protective effect.

The conventional photomask carrier is a square in shape, and a square placement space is formed on the inflation holder. The inflation connector is mounted corresponding to size and specification of the photomask carrier, so that the inflation connector can be connected to the photomask carrier and inflate gas into the photomask carrier. However, with the development of semiconductor manufacturing processes and EUV (extreme ultraviolet) exposure equipment, the size and specification of the photomask carrier will be adjusted to match the new exposure equipment. If the photomask carrier of the new exposure equipment is rectangular, the conventional inflation holder will not be suitable for the photomask carrier.

To overcome the shortcomings, the present invention provides an inflation holder for a photomask carrier to mitigate or obviate the aforementioned problems.

### SUMMARY OF THE INVENTION

The main objective of the present invention is to provide an inflation holder for a photomask carrier that is configured to be matched with a rectangular photomask carrier and capable of holding the rectangular photomask carrier.

The inflation holder for a photomask carrier comprises a plate body, a picking notch, multiple inflation connectors, and a detecting assembly.

The plate body is configured to be mounted on the carrying stand and comprises a loading area and a picking side. The loading area is rectangular and formed on a top of the plate body. The loading area is configured to be capable of holding the photomask carrier. The picking side is formed on a side of the plate body corresponding to a lengthwise side of the loading area.

The picking notch is formed on the plate body and extends from the picking side of the plate body toward the loading area. The inflation connectors are mounted through the plate body and located in the loading area of the plate body.

The detecting assembly comprises a detector and at least one press-switch. The detector is mounted on a periphery of the loading area of the plate body. The at least one press-switch is mounted in the loading area of the plate body. The detector and the at least one press-switch are capable of controlling the inflation connectors.

The inflation holder for a photomask carrier can hold the photomask carrier by the rectangular loading area of the plate body and control the inflation connectors by the detector and the at least one press-switch of the detecting assembly to ensure the flatness of the photomask carrier, so that the inflation connectors can inflate the photomask carrier, thereby allowing the inflation holder to be adapted to the rectangular photomask carrier.

Other objectives, advantages and novel features of the invention will become more apparent from the following detailed description when taken in conjunction with the accompanying drawings.

### BRIEF DESCRIPTION OF THE DRAWINGS

FIG. 1: is a perspective view of an inflation holder for a photomask carrier in accordance with the present invention;

FIG. 2 is another perspective view of the inflation holder for a photomask carrier in FIG. 1;

FIG. 3 is a perspective view of the inflation holder for a photomask carrier in FIG. 1 mounted on the carrying stand;

FIG. 4 is an enlarged view of the inflation holder for a photomask carrier mounted on the carrying stand in FIG. 3;

FIG. 5 is a front sectional view of the inflation holder for a photomask carrier mounted on the carrying stand in FIG. 4; and

FIG. 6 is a perspective view of the inflation holder for a photomask carrier mounted on the carrying stand in FIG. 3 with the photomask carrier.

### DETAILED DESCRIPTION OF THE PREFERRED EMBODIMENTS

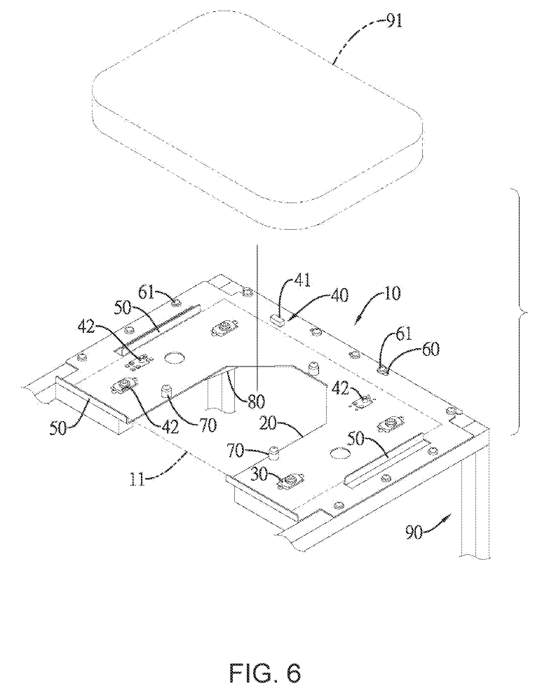

With reference to FIG. 6, an inflation holder for a photomask carrier in accordance with the present invention is configured to be mounted on a carrying stand 90 and capable of holding a photomask carrier 91. The inflation holder comprises a plate body 10, a picking notch 20, multiple inflation connectors 30, and a detecting assembly 40.

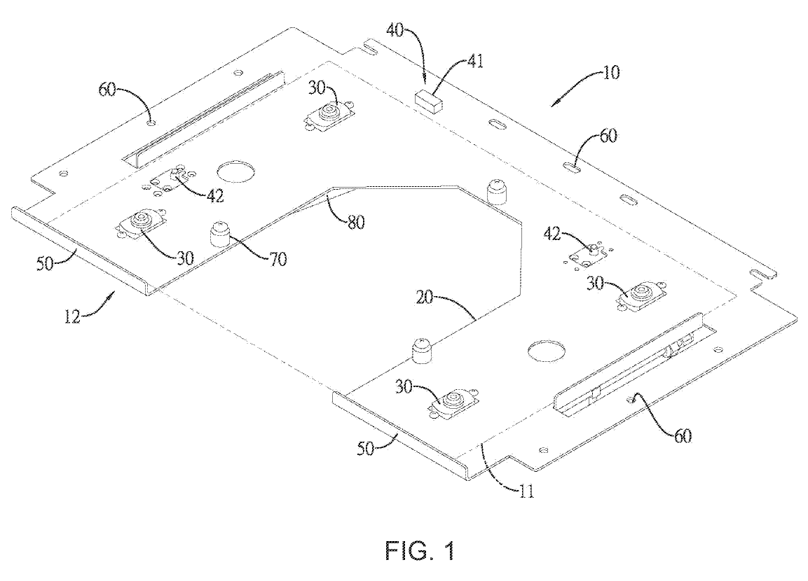

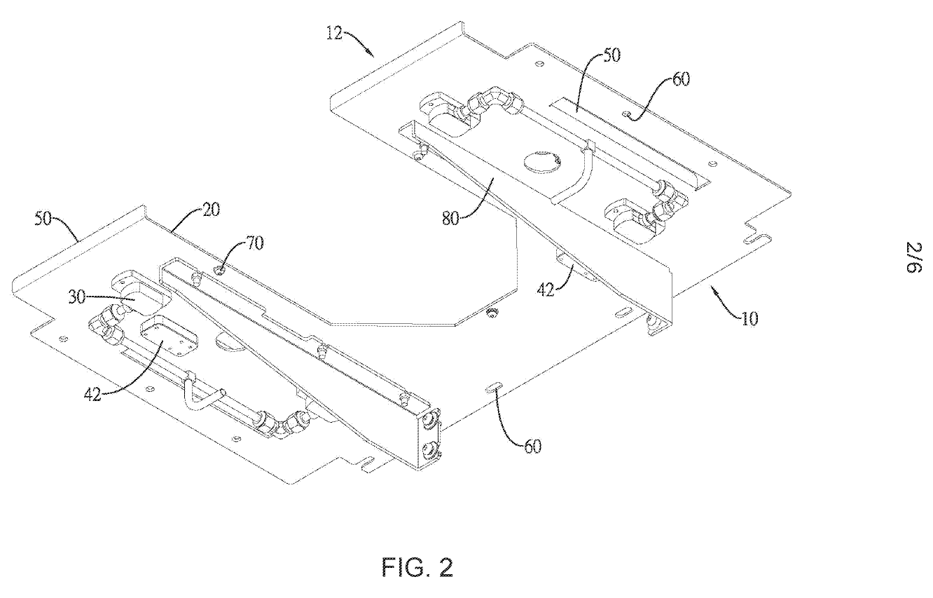

With reference to FIG. 1 to FIG. 2, the plate body 10 is configured to be mounted on the carrying stand 90 and comprises a loading area 11 and a picking side 12. In this embodiment, the plate body 10 is rectangular. The loading area 11 is formed on a top of the plate body 10 and can hold the photomask carrier 91. The loading area 11 is rectangular. The picking side 12 is formed on a side of the plate body 10 corresponding to a lengthwise side of the loading area 11.

With reference to FIG. 1 to FIG. 3, the picking notch 20 is formed on the plate body 10 and extends from the picking side 12 of the plate body 10 to an inside of the loading area 11.

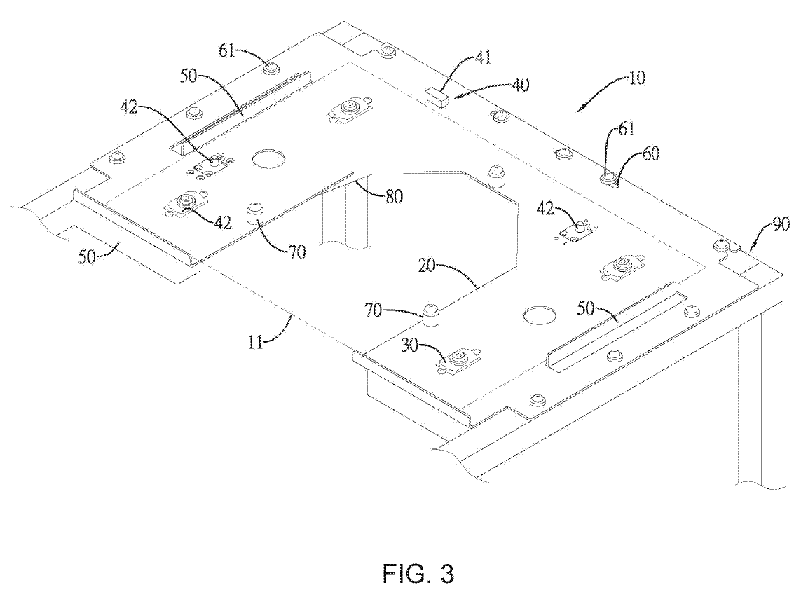

With reference to FIG. 3 to FIG. 5, the inflation connectors 30 are mounted through the plate body 10 and located in the loading area 11 of the plate body 10.

With reference to FIG. 1 to FIG. 3, the detecting assembly 40 comprises a detector 41 and at least one press-switch 42. The detector 41 is mounted on a periphery of the loading area 11 of the plate body 10, and the at least one press-switch 42 is mounted in the loading area 11 of the plate body 10. The detector 41 and the at least one press-switch 42 can control the multiple inflation connectors 30.

In addition, as shown in FIG. 3, the inflation holder for a photomask carrier can comprise multiple protrusions 70. The protrusions 70 are mounted around the picking notch 20 of the plate body 10.

With reference to FIG. 3 and FIG. 6, the inflation holder for a photomask carrier is mounted on the carrying stand 90 and can hold one rectangular photomask carrier 91. The detecting assembly 40 on the plate body 10 can be configured to determine if the photomask carrier 91 is properly placed. When properly placed in the loading area 11 of the plate body 10, the photomask carrier 91 will press the at least one press-switch 42, and the detector 41 will detect the photomask carrier 91 at the same time. If both the detector 41 and the at least one press-switch 42 detect the photomask carrier 91, a signal is sent to control the activation of the inflation connectors 30, so that the multiple inflation connectors 30 inflate the photomask carrier 91.

With reference to FIG. 3 and FIG. 6, in this embodiment, the inflation holder for a photomask carrier can comprise a plurality of the press-switches 42, the press-switches 42 are respectively mounted at diagonal positions of the loading area 11 of the plate body 10, and the press-switches 42 and the detector 41 are misaligned in position. Through multi-point detection of the detector 41 and the press-switches 42, the detection of the photomask carrier 91 is changed from single-point detection to plane detection, thereby ensuring that the photomask carrier 91 is placed horizontally on the loading area 11 of the plate body 10, to prevent the photomask carrier 91 from being tilted and affecting the inflation.

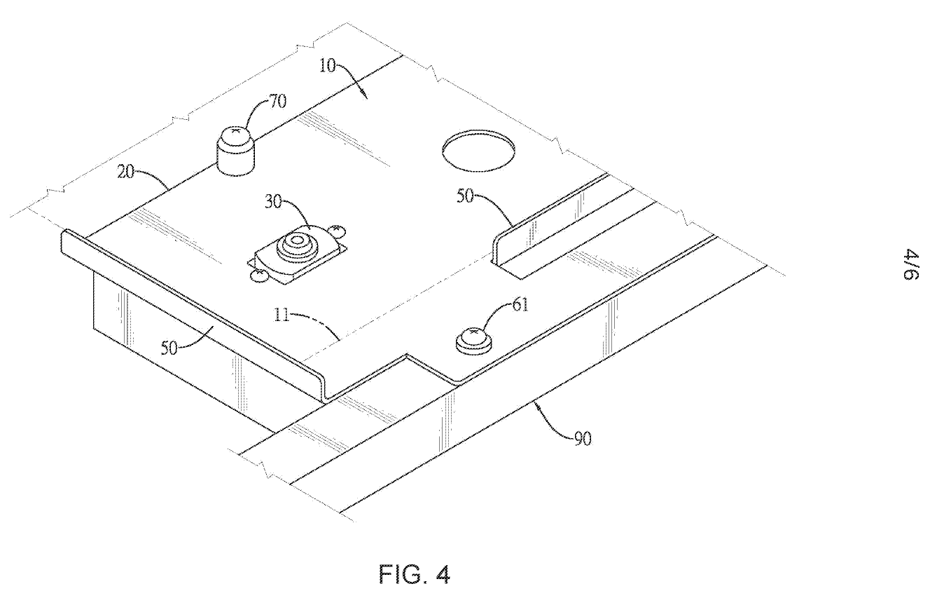

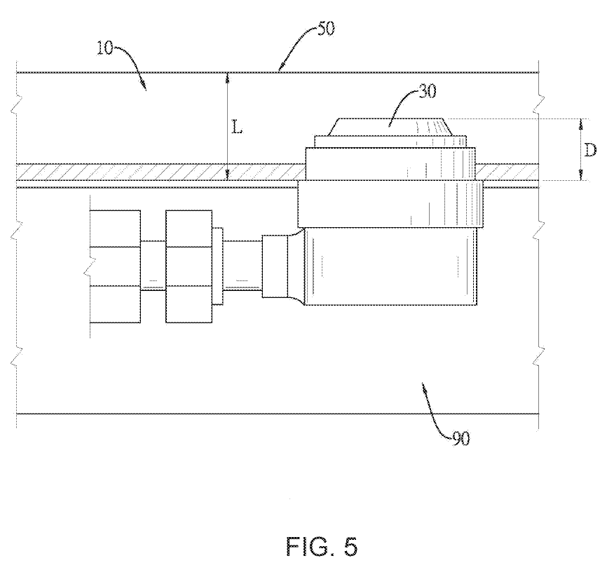

In addition, as shown in FIG. 4 and FIG. 5, in this embodiment, a distance D from a top of each one of the inflation connectors 30 to a bottom of the plate body 10 is greater than 1 mm. Therefore, when the photomask carrier 91 is placed in the loading area 11, the inflation connectors 30 can extend into and be assembled with the photomask carrier 91, thereby preventing the inflation connectors 30 and the photomask carrier 91 from forming gaps and affecting the inflation.

Furthermore, as shown in FIG. 3, considering different shapes and weights of the photomask carriers 91, the inflation holder for a photomask carrier can further comprise multiple locking holes 60 and multiple locking units 61 in this embodiment. The locking holes 60 are formed on the plate body 10 and located on other three sides of the plate body 10 relative to the picking side 12. The plate body 10 of the inflation holder for a photomask carrier can be locked on the carrying stand 90 by the locking units 61 respectively passing through the locking holes 60.

In addition, as shown in FIG. 2, the inflation holder for a photomask carrier can further comprise multiple supporting boards 80. The supporting boards 80 are mounted on the bottom of the plate body 10 and can be locked with the carrying stand 90. As shown in FIG. 2 and FIG. 3, by locking the three sides of the plate body 10 to the carrying stand 90 and installing the supporting boards 80, the support force provided by the carrying stand 90 to the plate body 10 can be improved. Therefore, the load of the photomask carrier 91 is dispersed and the flatness of the plate body 10 is increased, to prevent the plate body 10 from deformation due to overloading, thereby improving the structural strength of the photomask carrier 91.

Furthermore, as shown in FIG. 3 and FIG. 5, in this embodiment, the inflation holder for a photomask carrier can further comprise multiple locating blockers 50 formed on the plate body 10 and located around the loading area 11. A distance L from a top of the locating blocker 50 to the bottom of the plate body 10 is larger than 5 mm. In addition to assisting in positioning the photomask carrier 91, the locating blockers 50 can also limit the photomask carrier 91 and prevent the photomask carrier 91 from falling. The locating blocker 50 can block the photomask carrier 91 under vibration such as an earthquake to prevent the photomask carrier 91 from falling and being damaged.

The inflation holder for a photomask carrier can hold the photomask carrier 91 by the rectangular loading area 11 of the plate body 10 and control the inflation connectors 30 by the detector 41 and the at least one press-switch 42 of the detecting assembly 40 to ensure the flatness of the photomask carrier 91, so that the inflation connectors 30 can inflate the photomask carrier 91, thereby allowing the inflation holder to be adapted to the rectangular photomask carrier 91.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. An inflation holder for a photomask carrier configured to be mounted on a carrying stand and capable of holding a photomask carrier; the inflation holder comprising:
a plate body configured to be mounted on the carrying stand and comprising:
a loading area formed on a top of the plate body; the loading area configured to hold the photomask carrier; the loading area being rectangular; and
a picking side formed on a side of the plate body corresponding to a lengthwise side of the loading area;
a picking notch formed on the plate body and extending from the picking side of the plate body toward the loading area;
multiple inflation connectors mounted through the plate body and located in the loading area of the plate body; and
a detecting assembly comprising:
a detector mounted on a periphery of the loading area of the plate body; and
at least one press-switch mounted in the loading area of the plate body; the detector and the at least one press-switch being capable of controlling the inflation connectors.

2. The inflation holder as claimed in claim 1, wherein the inflation holder includes a plurality of the press-switches; the multiple press-switches are respectively mounted at diagonal positions of the loading area of the plate body, and the multiple press-switches and the detector are misaligned in position.

3. The inflation holder as claimed in claim 1, wherein a distance between a top of each one of the inflation connectors and a bottom of the plate body is greater than 1 millimeter(mm).

4. The inflation holder as claimed in claim 2, wherein a distance between a top of each one of the inflation connectors and a bottom of the plate body is greater than 1 mm.

5. The inflation holder as claimed in claim 1, wherein the inflation holder comprises multiple locating blockers; the locating blockers are formed on the plate body and located around the loading area.

6. The inflation holder as claimed in claim 4, wherein the inflation holder comprises multiple locating blockers; the locating blockers are formed on the plate body and located around the loading area.

7. The inflation holder as claimed in claim 5, wherein a distance between a top of each one of the locating blockers and a bottom of the plate body is greater than 5 mm.

8. The inflation holder as claimed in claim 6, wherein a distance between a top of each one of the locating blockers and the bottom of the plate body is greater than 5 mm.

9. The inflation holder as claimed in claim 1, wherein the inflation holder comprises:
multiple locking holes formed on the plate body and located on other three sides of the plate body relative to the picking side; and
multiple locking units respectively mounted through the locking holes; the plate body of the inflation holder configured to be locked on the carrying stand by passing the locking units through the locking holes.

10. The inflation holder as claimed in claim 8, wherein the inflation holder comprises:
multiple locking holes formed on the plate body and located on other three sides of the plate body relative to the picking side; and
multiple locking units respectively mounted through the locking holes; the plate body of the inflation holder configured to be locked on the carrying stand by passing the locking units through the locking holes.

11. The inflation holder as claimed in claim 1, wherein the inflation holder comprises multiple protrusions; the protrusions are mounted around the picking notch of the plate body.

12. The inflation holder as claimed in claim 10, wherein the inflation holder comprises multiple protrusions; the protrusions are mounted around the picking notch of the plate body.

13. The inflation holder as claimed in claim 1, wherein the inflation holder comprises multiple supporting boards; the supporting boards are mounted on a bottom of the plate body and are capable of being locked with the carrying stand.

14. The inflation holder as claimed in claim 12, wherein the inflation holder comprises multiple supporting boards; the supporting boards are mounted on the bottom of the plate body and are capable of being locked with the carrying stand.
